(19) United States
(12) Patent Application Publication
(10) Pub. No.: US 2010/0159397 A1
(43) Pub. Date: Jun. 24, 2010

(54) Method and System for Forming a Data Recording Medium

(76) Inventor: Manish Sharma, Palo Alto, CA (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/711,169

(22) Filed: Feb. 23, 2010

Related U.S. Application Data
(62) Division of application No. 11/285,851, filed on Nov. 22, 2005.

(51) Int. Cl. G03F 7/20; G03B 27/42

(52) U.S. Cl. 430/320; 355/53

(57) ABSTRACT

An embodiment of a method of forming a data recording medium includes the initial step of applying a resist material to a surface of a keepered medium. The embodiment of the method also includes the step of forming the resist material into a three-dimensional resist structure that corresponds to a pattern that is to be applied to the keepered media.

### FIELD OF THE INVENTION

The present invention relates generally to the field of data recording media, and more particularly to a method and system for forming a data recording medium.

### BACKGROUND OF THE INVENTION

Conventional data storage devices, such as a computer hard disk, include a platter that has a magnetic data recording layer in the form of a thin film of magnetic alloy. The thin film of magnetic alloy naturally forms a random mosaic of nanometer-scale grains that behave as independent magnetic elements. Each bit of data that is stored on the magnetic data recording layer is represented by one hundred or so, weakly interacting, grains.

Over the past decade the areal density of the magnetic data recording layer has increased significantly due by and large to a reduction in the number of grains used to represent a bit and a reduction in the size of the grains. Whilst these two techniques have yielded impressive areal density increases, they do have limitations that will in the near future restrict their ability to provide further increases in the areal density of the magnetic recording layer.

A limitation associated with reducing the number of grains to represent a bit is that it results in a decrease in the signal-to-noise ratio of recorded data. A decrease in the signal-to-noise ratio can make it difficult, if not impossible, to detect recorded data.

Another limitation associated with reducing the size of the grains is that the magnetic energy per bit becomes comparable to the thermal energy of a grain, which can result in the grains undergoing spontaneous magnetisation reversals. This characteristic is known as “superparamagnetism” and can result in loss of stored data.

### SUMMARY OF THE INVENTION

An embodiment of a method of forming a data recording medium includes the initial step of applying a resist material to a surface of a keepered medium. The embodiment of the method also includes the step of forming the resist material into a three-dimensional resist structure that corresponds to a pattern that is to be applied to the keepered medium.

The present invention will be more fully understood from the following description of a specific embodiment. The description is provided with reference to the accompanying drawings.

### BRIEF DESCRIPTION OF THE DRAWINGS

FIG. 1 is a schematic diagram of a system in accordance with an embodiment of the present invention;

FIG. 2(a) is a cross-sectional view of a keepered medium that can be processed by the system of FIG. 1 in accordance with an embodiment of the present invention;

FIG. 2(b) is a cross-sectional view of a keepered medium that has been subjected to a processing step of the system of FIG. 1 in accordance with an embodiment of the present invention;

FIG. 2(c) is a perspective view of the keepered medium shown in FIG. 2(b) that has been subjected to another processing step of the system of FIG. 1 in accordance with an embodiment of the present invention;

FIG. 2(d) is a perspective view of the keepered medium shown in FIG. 2(c) that has been subjected to yet another processing step of the system of FIG. 1 in accordance with an embodiment of the present invention; and

FIG. 2(e) is a perspective view of the keepered medium shown in FIG. 2(d) in accordance with an embodiment of the present invention.

FIG. 3 is a flow chart of the various steps of a patterning process performed by the system of FIG. 1 in accordance with an embodiment of the present invention;

### DETAILED DESCRIPTION

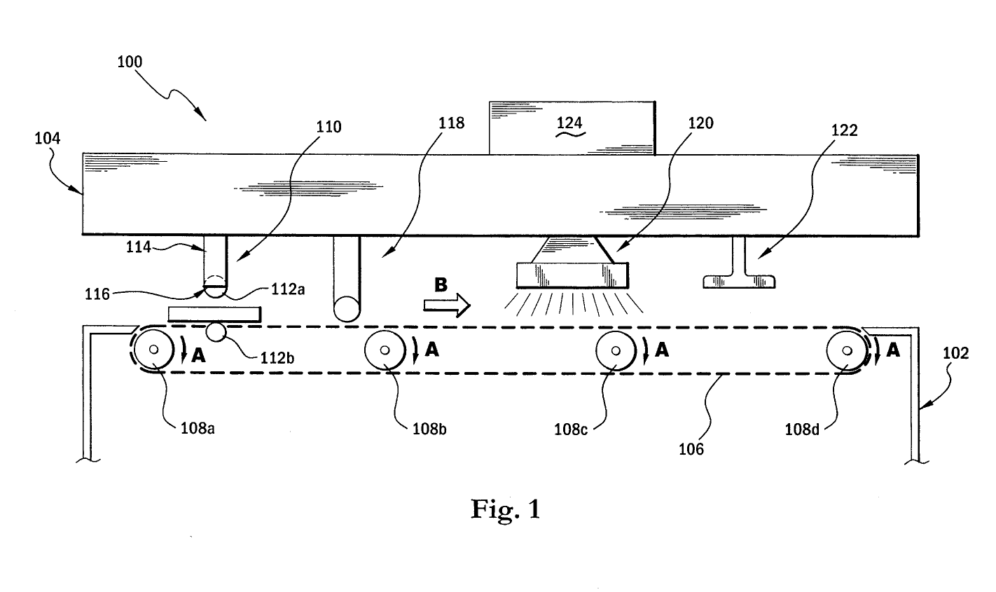

FIG. 1 shows a system 100 in accordance with an embodiment of the present invention. The system 100 includes a lower support structure 102 and an upper support structure 104. In addition to the support structures 102 and 104, the system 100 includes a conveyor belt 106 that is in the form of a continuous belt, and several spaced apart electrically driven belt drives 108 that are mounted to the lower support structure 102. The conveyor belt 106 is fitted to the belt drives 108.

The system 100 also includes an applicator component 110 in the form of a gravure coater. The applicator component 110 is mounted to the upper support structure 104 and supported thereby in the vicinity of the conveyor belt 106. The applicator component 110 includes opposed rollers 112, a receptacle 114 and a blade 116. As discussed in more detail in the subsequent paragraphs of this specification, the opposed rollers 112, the receptacle 114 and the blade 116 cooperate to apply a resist material to an object passing between the rollers 112.

In addition to the applicator component 110, the system 100 includes a stamping tool 118 that is in the form of an imprinting roller. The stamping tool 118 is mounted to the upper support structure 104 and is supported thereby in the vicinity of the conveyor belt 106. The system 100 also includes a curing component 120 in the form of an ultraviolet light lamp. The curing component 120 is coupled to the upper support structure 104 and is supported thereby at a position near the conveyor belt 106. The system 100 includes an etching component 122 and an electronic controller 124. The etching component 122 is in the form of an ion emitter, while the electronic controller 124 is in the form of a programmable logic controller that is electrically coupled to the system 100.

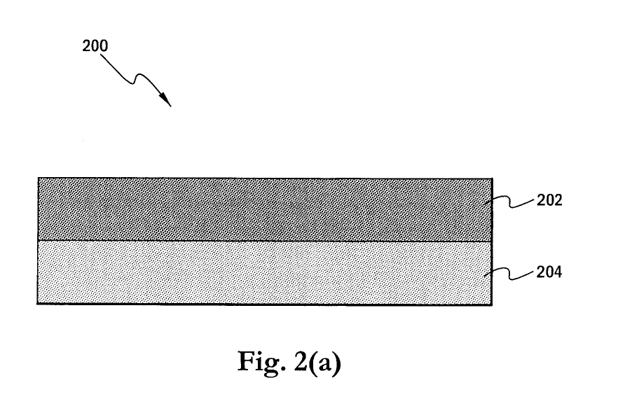

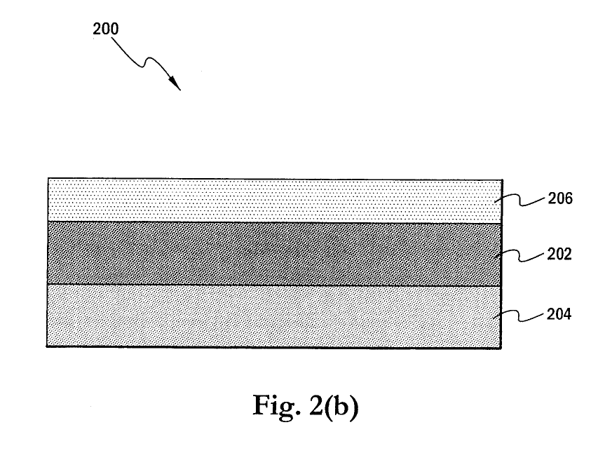

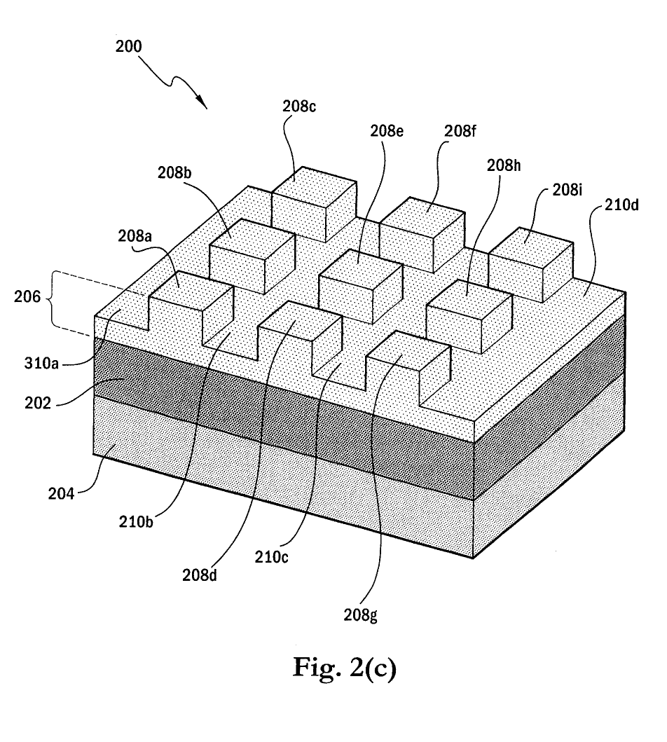

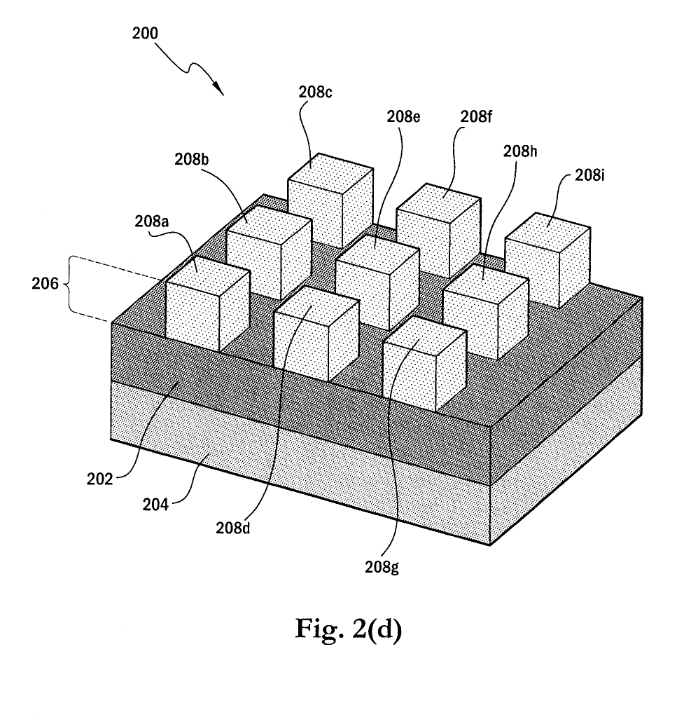

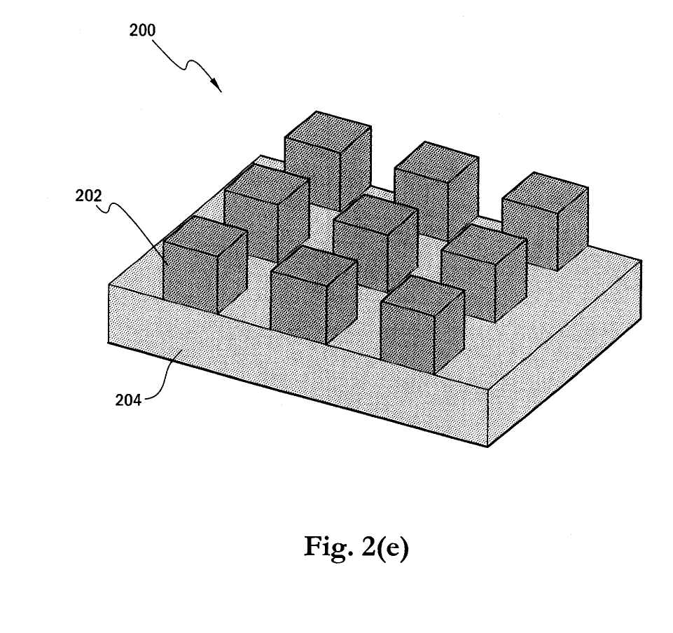

The system 100 enables a pattern to be applied to a surface of a keepered data recording medium 200, which is shown in FIG. 2(a). The keepered data recording medium 200 can, for example, be incorporated in to a platter of a computer hard disk storage device. As with traditional recording mediums found in computer hard disks, the keepered data recording medium 200 can be used to store a range of electronic data including, for example, digital images and video clips. A potential advantage of patterning the surface of the keepered data recording medium 200 is that it increases the areal density of the medium 200 compared to a non-patterned medium 200.

The keepered data recording medium 200 includes a first magnetic layer 202 that has an intrinsic coercivity of around 24 kA/m or more. In light of the intrinsic coercivity of the first magnetic layer 202, persons skilled in the art refer to the first magnetic layer 202 as being a “hard magnetic layer”. The first magnetic layer 202 is made of a CoCrPt material and is around 30 nm thick. The keepered data recording medium also includes a second magnetic layer 204 that has an intrinsic coercivity of less than around 24 kA/m. Persons skilled in the art refer to the second magnetic layer 204 as being a “soft magnetic layer” because of its intrinsic coercivity. The second magnetic layer 204 is made from a HITPERM type alloy and is around 100 nm thick. The second magnetic layer 204 basically increases the magnetic field of a write head used to read data from the keepered data recording medium 200. Increasing the magnetic field enables the superparamagnetic limit to be extended by allowing fewer and smaller grains in the first magnetic layer 202 to be used to represent a bit.

As indicated previously, the system 100 enables a pattern to be applied to the surface of the keepered data recording medium 200. In this regard, the keepered data recording medium 200 is initially placed on the conveyor belt 106 near the belt drive 108a. The conveyor belt 106 effectively transports the keepered data recording medium 200 (when placed on the conveyor belt 106) in the direction indicated by the arrow marked “B”. To enable the conveyor belt 106 to transport the keepered data recording medium 200 in the direction of the arrow marked “B”, the belt drives 108 are arranged such that when powered-up they rotate in the direction indicated by the arrow marked “A”. The electronic controller 124 is arranged to control the power used to effect rotation of the belt drives 108. More specifically, the electronic controller 124 is arranged to, for example, turn the power provided to the belt drives 108 on and off.

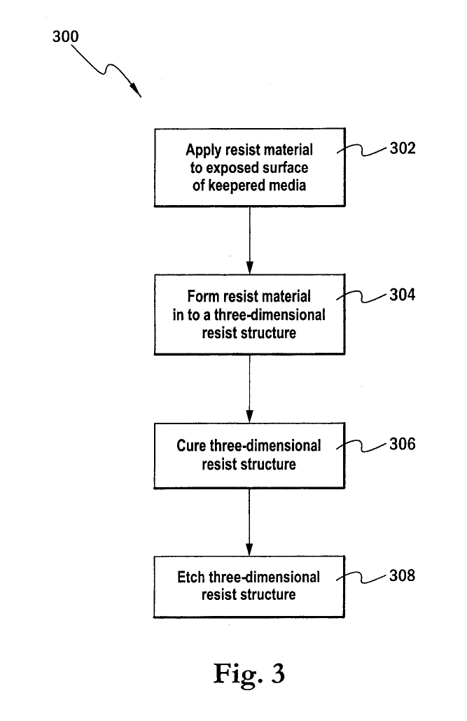

As the keepered data recording medium 200 is transported (by the conveyor belt 106) in the direction of the arrow “B” the keepered data recording medium 200 is subjected to a patterning process that includes several steps 302 to 308. The steps 302 to 308 of the patterning process are shown in the flow chart 300 of FIG. 3. The first step 302 of the patterning process is performed by the applicator component 110 and involves applying a resist material on to the first magnetic layer 202. The resist material is in the form of a commercially available resist polymer, such as one of those available from the Norland optical adhesives family of polymers, that is a liquid photopolymer.

In order to perform the first step 302 of applying the resist material, the keepered data recording medium 200 passes between the rollers 112, which are arranged to rotate in an anti-clockwise direction so as to allow the movement of the keepered medium 200 in the direction of arrow “B”. The upper roller 112a, which is partly submerged in the resist material contained in the receptacle 114, is coated with the resist material as the upper roller 112a rotates. The blade 116 controls the thickness of the resist material coating on the upper roller 112a, which in turn determines the thickness of the resist material applied to the keepered medium 200. As the keepered medium 200 passes between the rollers 112 the medium 200 comes in to contact with the rollers 112, which causes a layer of resist material to be applied to the first magnetic layer 202. The blade 116 is such that the thickness of the resist material applied to the first magnetic layer 202 is around 1 nm. FIG. 2(b) shows a cross-sectional view of the keepered medium 200 with a layer of the resist material 206 on the first magnetic layer 202.

As the keepered medium 200 egresses from between the rollers 112 of the applicator component 110, with the layer of the resist material 206, the conveyor belt 106 continues to transport the keepered medium 200 in the direction of the arrow “B” so that the medium 200 can be subjected to a second step 304 of the patterning process. The second step 304 involves forming the layer of resist material 206 on the first magnetic layer 202 in to a three-dimensional resist structure. The second step 304 is performed by the stamping tool 118, which as mentioned previously is in the form of an imprinting roller that rotates in an anti-clockwise direction. The stamping tool 118 has a surface that defines a three-dimensional structure that is to be imprinted (transferred) in the layer of resist material 206 on the first magnetic layer 202. As the keepered medium 200 moves in the direction of the arrow “B” the layer of resist material 206 on the first magnetic layer 202 comes in to contact with the stamping tool 118, which displaces the layer of resist material 206 in to the three-dimensional structure of the stamping tool 118. FIG. 2(c) shows a perspective view of the layer of resist material 206 that has been displaced by the stamping tool 118.

As can be seen in FIG. 2(c), the displaced three-dimensional resist material 206 includes a plurality of first elements 208 that protrude above a plurality of second elements 210. Consequently, each first element 208 has a height dimension that is different to a height dimension of the each of the second elements 210. The first elements 208 are arranged so as to form a matrix like pattern. While the matrix like pattern shown in FIG. 2(c) depicts the elements 208 and 210 arranged in a substantially square grid, it is envisaged that in alternative embodiments of the present invention the matrix like pattern includes a series of concentric spiral or parallel tracks arranged in a circular geometry. While the first elements 208 are shown in FIG. 2(c) as being in the form of a cube, it is envisaged that in alternative embodiments of the present invention the first elements 208 could be in other forms including cylindrical, elliptical or rectangular.

As the keepered data recording medium 200 egresses from the stamping tool 118 the conveyor belt 106 continues to transport the keepered medium 200 in the direction of the arrow “B” so that the medium 200 can be subjected to a third step 306 of the patterning process. The third step 306 of the patterning process is performed by the curing component 120, which as mentioned previously is in the form of an ultraviolet lamp. As the keepered medium 200 passes under the curing component 120 the layer of resist material 206 is exposed to ultraviolet electromagnetic radiation, in the range of 320 to 380 nm, emanating from the curing component 120. When exposed to the ultraviolet electromagnetic radiation the layer of resist material 206 cures; that is, the layer of resist material 206 solidifies.

The conveyor belt 106 transports the keepered medium 200 away from the curing component 120 and towards the etching component 122, which performs the final step 308 of the patterning process. The final step 308 involves etching away the cured three-dimensional resist layer 206 to thereby transfer the three-dimensional pattern (of the resist layer 206) to the keepered medium 200. To etch away the three-dimensional resist layer 206, the etching component 122 (which as mentioned previously is in the form of an ion emitter) performs an anisotropic etching technique that involves bombarding the resist layer 206 with energetic and chemically inert ions in a non-selective manner. The non-selective manner basically means that the ions are applied to the entire surface of the resist layer 206. Ions emitted from the etching component 122 collide with atoms of the resist layer 206 as they hit the surface of the resist layer 206. As the ions collide with the atoms of the resist layer 206 the atoms are dislodged (removed) to thereby etch away the resist layer 206.

FIG. 2(d) shows a perspective view of the keepered medium 200 after being subjected to the final etching step 308 for an initial period of time. In can be seen that the resist layer 206 only includes the plurality of first elements 208. The plurality of second elements 210, which are shown in FIG. 2(c) have been etched away by the ions emitted from the etching component 122. FIG. 2(e) provides a perspective view of the keepered medium 200 that has been subjected to the final etching step 208 for a further period of time. It can be seen in FIG. 2(e) that the resist layer 206 has been completely etched away.

An effect of the etching step 308 is that the keepered medium 200 has a patterned first magnetic layer 202, which potentially provides an advantage of increasing the areal density of the keepered medium 200 when compared to a non-patterned keepered medium 200. The increase in the areal density of the keepered medium 200 stems from the pattern's ability to ameliorate statistical noise associated with granular (non-patterned) media.

It will be readily appreciated by those skilled in the art that while the present embodiment of the invention has been described in relation to a single layer of resist material 206 that is subjected to a single etching step 308, other embodiments of the present invention could employ multiple layers of the resist material 206 each of which is subjected to a separate etching step 308.

1. A method of forming a data recording medium, the method comprising the steps of:
applying a resist material to a surface of a keepered medium; and
forming the resist material into a three-dimensional resist structure that corresponds to a pattern that is to be applied to the keepered medium.

2. The method as claimed in claim 1, wherein the step of forming the resist material comprises the step of imprinting the resist material to form the three-dimensional resist structure.

3. The method as claimed in claim 1, further comprising the step of curing the three-dimensional resist structure.

4. The method as claimed in claim 3, wherein the step of curing the three-dimensional resist structure comprises the step of exposing the three-dimensional resist structure to ultraviolet electromagnetic radiation.

5. The method as claimed in claim 3, further comprising the step of etching the three-dimensional resist structure to apply the pattern to the keepered medium.

6. The method as claimed in claim 5, wherein the step of etching the three-dimensional resist structure comprises an anisotropic etch process.

7. The method as claimed in claim 1, wherein the three-dimensional structure comprises a plurality of elements, wherein at least one of the elements has a first height dimension that is different to a second height dimension of another of the elements.

8. The method as claimed in claim 7, wherein the pattern is such that the elements are arranged to form a matrix.

9. A system for forming a data recording medium, the system comprising:
an applicator component for applying a resist material to a surface of a keepered medium; and
a forming component for forming the resist material into a three-dimensional resist structure that corresponds to a pattern that is to be applied to the keepered medium.

10. The system as claimed in claim 9, wherein forming component is arranged to imprint the resist material so as to form the three-dimensional resist structure.

11. The system as claimed in claim 9, further comprising a curing component for curing the three-dimensional resist structure.

12. The system as claimed in claim 11, wherein the curing component is arranged to expose the three-dimensional resist structure to ultraviolet electromagnetic radiation so as to cure the three-dimensional resist structure.

13. The system as claimed in claim 11, further comprising an etching component for etching the three-dimensional resist structure so as to apply the pattern to the keepered medium.

14. The system as claimed in claim 13, wherein the etching component is arranged to use an anisotropic etch process in order to etch the three-dimensional resist structure.

15. The system as claimed in claim 1, wherein the three-dimensional structure comprises a plurality of elements, wherein at least one of the elements has a first height dimension that it different to a second height dimension of another of the elements.

16. The system as claimed in claim 15, wherein the pattern is such that the elements are arranged to form a matrix.

17-32. (canceled)

33. The method as claimed in claim 5, wherein the keepered material comprises a first layer of a first magnetic material and a second layer of a second magnetic material, and the step of etching the three-dimensional resist structure further comprises etching portions of the first layer to leave magnetic elements of the first material on the second layer.

34. The method of claim 33, wherein the first magnetic material has a first intrinsic coercivity that is higher than a second intrinsic coercivity of the second magnetic material.
